(19) United States
(12) Patent Application Publication
(10) Pub. No.: US 2005/0031836 A1
(43) Pub. Date: Feb. 10, 2005

(54) Pattern forming method, pattern forming apparatus, device manufacturing method, conductive film wiring, electro-optical device, and electronic apparatus

(76) Inventor: Toshimitsu Hirai, Chino-Shi (JP)

Correspondence Address: HARNESS, DICKEY & PIERCE, P.L.C., P.O. BOX 828, BLOOMFIELD HILLS, MI, 48303, US

(21) Appl. No.: 10/809,205

(22) Filed: Mar. 25, 2004

(30) Foreign Application Priority Data
Mar. 27, 2003 (JP) 2003-088803
Feb. 6, 2004 (JP) 2004-031045

(51) Int. Cl. H01L 25/00; B05D 5/00; H05K 3/00

(52) U.S. Cl. 428/209; 427/421.1; 427/256; 118/300

(57) ABSTRACT

A pattern forming method is provided for forming film patterns W1 to W3 by arranging droplets of a liquid material on a substrate. The method comprises the steps of: defining a plurality of pattern forming areas R1 to R3 in which the film patterns should be formed on the substrate; and sequentially arranging a plurality of droplets in the plurality of defined pattern forming areas R1 to R3, thereby forming the film patterns W1 to W3, wherein the droplets are sequentially arranged by setting an arrangement order of the droplets to be substantially equal for the plurality of pattern forming areas R1 to R3.

### RELATED APPLICATIONS

This application claims priority to Japanese Patent Application Nos. 2003-088803 filed Mar. 27, 2003 and 2004-031045 filed Feb. 6, 2004 which are hereby expressly incorporated by reference herein in their entireties.

### BACKGROUND

1. Technical Field of the Invention

The present invention relates to a pattern forming method and a pattern forming apparatus for forming a film pattern by arranging droplets of a liquid material on a substrate, a method of manufacturing a device, conductive film wiring, an electro-optical device, and an electronic apparatus.

2. Description of the Related Art

Photolithographic methods have been widely used in methods of manufacturing devices having a fine wiring pattern (film pattern), such as a semiconductor integrated circuit (IC). However, a lot of attention has been paid to a method of manufacturing a device using a droplet discharge method. The droplet discharge method has an advantage in that the consumption of a liquid material is less wasteful and the amount or position of the liquid material disposed on the substrate is easily controlled. Techniques concerning a droplet discharge method are disclosed in Japanese Unexamined Patent Application Publication No. 11-274671 and Japanese Unexamined Patent Application Publication No. 2000-216330.

On the other hand, when a plurality of wiring patterns are formed by arranging a plurality of droplets on a substrate, arrangement of the droplets may be different for each wiring pattern, so that there is a problem that a lack of uniformity in appearance between the wiring patterns occurs. Further, when the wiring patterns have a large line width, the droplets may be arranged in a line-width direction, but deviation in the line width may occur, for example, in a case where the droplets for forming both end portions in the line-width direction are first arranged and then the droplets for forming a central portion are arranged to fill a space between both end portions, or in a case where the central portion in the line-width direction is first formed and then the droplets for forming both end portions are arranged. That is, when the central portion in the line-width direction is first formed and then the droplets for forming both end portions are arranged, a phenomenon that the droplets are drawn toward the central portion occurs, so that the line width thereof may be narrowed, compared with a case where both ends are first formed and then the central portion is formed.

The present invention is contrived to solve the above problems, and it is an object of the present invention to provide a pattern forming method, a pattern forming apparatus, and a device manufacturing method, which are capable of preventing generation of deviation in line width between film patterns or lack of uniformity in appearance when forming a plurality of film patterns by arranging droplets of liquid material on a substrate. It is also another object of the present invention to provide conductive film wiring in which deviation in line width is suppressed, an electro-optical device having the conductive film wiring, and an electronic apparatus employing the electro-optical device.

### SUMMARY

In order to accomplish the above object, the present invention provides a pattern forming method of forming film patterns by arranging droplets of a liquid material on a substrate, the method comprising the steps of: defining a plurality of pattern forming areas in which the film patterns should be formed on the substrate; and sequentially arranging a plurality of droplets in the plurality of defined pattern forming areas, thereby forming the film patterns, wherein the droplets are sequentially arranged by setting an arrangement order of the droplets to be substantially equal in the plurality of pattern forming areas.

According to the present invention, when the plurality of droplets are sequentially arranged for forming the film patterns, the arrangement order is set to be substantially equal in the plurality of film patterns, so that the deviation in a line width between the film patterns or the lack of uniformity in appearance can be suppressed.

In this case, a shape of the film patterns or the order of arranging the droplets may be set to be smoothly and substantially equal to each other, by defining a plurality of unit areas having a lattice shape in which the droplets should be arranged on the substrate, and arranging the droplets in a predetermined unit area of the plurality of unit areas.

In the pattern forming method according to the present invention, the droplets may be arranged almost simultaneously in the plurality of pattern forming areas.

According to the present invention, by comprising a step of arranging simultaneously the droplets in the plurality of pattern forming areas, it is possible to accomplish enhancement of throughput.

In the pattern forming method according to the present invention, the film patterns may be line-shaped patterns, side portions in a line-width direction of the film patterns may be first formed and then central portions thereof may be formed, or the central portions in the line-width direction of the film patterns may be first formed and then the side portions may be formed.

According to the present invention, the line widths of the plurality of line-shaped patterns can be set to be substantially equal. That is, in a case where the central portions of the line-shaped patterns are first formed and then the droplets for forming the side portions are arranged, it should be considered that a phenomenon that the droplets are drawn toward the central portions occurs due to the setting of the arrangement of the droplets to be substantially equal, thereby generating the deviation in a line width of the line-shaped patterns. However, by forming both side portions of the line-shaped patterns and then arranging the droplets for forming the central portions to fill spaces between both side portions, the deviation in a line width of the line-shaped patterns can be prevented from occurring.

In the pattern forming method according to the present invention, the plurality of pattern forming areas may be arranged and defined in a predetermined direction, a plurality of discharge portions for arranging the droplets may be provided corresponding to the plurality of pattern forming areas, respectively, and the droplets may be arranged while moving the discharge portions in the arrangement direction of the pattern forming areas.

According to the present invention, since the discharge portions (discharge nozzles) are provided corresponding to the plurality of pattern forming areas, respectively, and the droplets are arranged while moving the discharge portions, the plurality of film patterns (wiring patterns) can be formed in a short time.

In the pattern forming method according to the present invention, the liquid material comprises conductive particles. As a result, the conductive film can be formed without the deviation in a line width or the lack of uniformity in appearance between the film patterns.

The present invention also provides a pattern forming method of forming line-shaped film patterns by arranging droplets of a liquid material on a substrate, the method comprising the steps of: arranging and defining a plurality of pattern forming areas in which the film patterns should be formed on the substrate; and arranging the plurality of droplets in the plurality of defined pattern forming areas to overlap a part thereof, thereby forming the film patterns, wherein the arrangement of the droplets is set to be substantially equal in the plurality of pattern forming areas.

According to the present invention, since the droplets are arranged to overlap at least a part of the droplets when the plurality of droplets are arranged on the substrate to form the film patterns, generation of discontinuous portions of the film patterns can be prevented. Since the arrangement of the droplets is set to be substantially equal in the film patterns when the droplets are arranged to overlap a part thereof, the lack of uniformity in appearance of the plurality of film patterns can be prevented from occurring.

The present invention provides a pattern forming apparatus comprising a droplet discharge device for arranging droplets of a liquid material on a substrate and forming film patterns out of the droplets, wherein the droplet discharge device sequentially arranges the plurality of droplets in a plurality of pattern forming areas which are defined in advance on the substrate and in which the film patterns should be formed, and when the droplets are sequentially arranged, an arrangement order of arranging the droplets is set to be substantially equal in the plurality of pattern forming areas.

According to the present invention, since the arrangement order is set to be substantially equal in the plurality of film patterns when sequentially arranging the plurality of droplets to form the film patterns, the deviation in a line width or the lack of uniformity in appearance can be prevented from occurring.

The present invention also provides a pattern forming apparatus comprising a droplet discharge device for arranging droplets of a liquid material on a substrate and forming line-shaped film patterns out of the droplets, wherein the droplet discharge device arranges the plurality of droplets in a plurality of pattern forming areas which are defined in advance on the substrate and in which the film patterns should be formed, to overlap a part thereof, and the arrangement of the droplets is set to be substantially equal in the plurality of pattern forming areas.

According to the present invention, when forming the film patterns, the discontinuous portions of the film patterns can be prevented from being generated, and the lack of uniformity in appearance of the plurality of film patterns can be prevented from occurring.

The present invention provides a method of manufacturing a device having wiring patterns, the method comprising: a material arranging step of forming the wiring patterns by arranging droplets of a liquid material in a plurality of pattern forming areas which are defined on a substrate and in which the wiring patterns should be formed, wherein the material arranging step comprises a step of forming the film patterns by sequentially arranging the plurality of droplets in the plurality of defined pattern forming areas, and wherein the droplets are sequentially arranged by setting an arrangement order of the droplets to be substantially equal in the plurality of pattern forming areas.

According to the present invention, since the arrangement order is set to be substantially equal in the plurality of wiring patterns when sequentially arranging the plurality of droplets to form the wiring patterns, the deviation in a line width or the lack of uniformity in appearance can be prevented from occurring.

The present invention also provides a method of manufacturing a device having wiring patterns, the method comprising: a material arranging step of forming the wiring patterns by arranging droplets of a liquid material in a plurality of pattern forming areas which are defined on a substrate and in which the wiring patterns should be formed, wherein the material arranging step comprises a step of forming the film patterns by arranging the plurality of droplets in the plurality of defined pattern forming areas to overlap a part thereof, and wherein the arrangement of the droplets is set to be substantially equal in the plurality of pattern forming areas.

According to the present invention, when forming the wiring patterns, the discontinuous portions of the wiring patterns can be prevented from being generated, and the lack of uniformity in appearance of the plurality of wiring patterns can be also prevented from occurring.

By applying the film pattern forming method or the wiring pattern forming method to a case of manufacturing wiring lines (display electrodes, etc.) to be arranged in a display unit of a plasma type display device, wiring patterns without the lack of uniformity in appearance can be formed, so that it is possible to obtain an excellent display property or visibility.

Furthermore, for example, a thin film transistor is formed by stacking a plurality of functional layers including wiring lines, and by applying the present invention to the manufacture of the respective functional layers (wiring lines) of the thin film transistor, the deviation in a film thickness as well as the deviation in a line width of a predetermined layer can be prevented from occurring, so that it is possible to prevent the deviation in a thickness from being generated in an in-plane direction of the thin film transistor when the plurality of functional layers are stacked.

The present invention also provides conductive film wiring formed using the pattern forming apparatus.

According to the present invention, it is possible to provide conductive film wiring with a uniform line width and without the lack of uniformity in appearance.

The present invention provides conductive film wiring comprising a plurality of wiring patterns arranged on a substrate, wherein the plurality of wiring patterns are formed out of a plurality of droplets arranged to overlap a part thereof, and the arrangement of the plurality of droplets is set to be substantially equal in the plurality of wiring patterns.

According to the present invention, it is possible to provide conductive film wiring without the lack of uniformity in appearance.

The present invention also provides an electro-optical device comprising the aforementioned conductive film wiring. In addition, the present invention also provides an electronic apparatus comprises the aforementioned electro-optical device. According to the present invention, since the conductive film pattern having a uniform line width and not having the lack of uniformity in appearance is provided, it is possible to obtain excellent electrical characteristic and display property.

Here, the electro-optical device may include a plasma display device, a liquid crystal display device, and an organic field emission display device.

The droplet discharge methods of the droplet discharge device (ink jet device) discharge may include a piezo-jet method of discharging a liquid material by a variation in volume of a piezoelectric element and a method of discharging droplets of a liquid material by rapidly generating vapor due to applied heat.

The liquid material means a medium having viscosity that can be discharged through a discharge nozzle of a droplet discharge head (ink jet head). Whether the liquid material is watery or oily does not matter. Any liquid material may be used as long as fluidity (viscosity) that can be discharged through a nozzle is given thereto, and any fluid in which a solid material is mixed, may be used as long as it has fluidity as a whole. In addition, a material included in the liquid material may be a material dispersed in a solvent as particles as well as a material heated and melted above a melting point, or a material to which dyes, pigments or other functional materials may be added in addition to a solvent. In addition, the substrate may be a flat substrate or a curved substrate. Further, the hardness of a pattern formation surface need not be large, and the pattern formation surface may be formed of glass or plastics, metal, or a material having flexibility, such as film, paper, or rubber.

### BRIEF DESCRIPTION OF THE DRAWINGS

FIG. 1 is a flowchart illustrating a pattern forming method according to an embodiment of the present invention.

FIGS. 2A-B are mimetic diagrams illustrating the pattern forming method according to the embodiment of the present invention.

FIGS. 3A-B are mimetic diagrams illustrating the pattern forming method according to the embodiment of the present invention.

FIGS. 4A-B are mimetic diagrams illustrating the pattern forming method according to the embodiment of the present invention.

FIGS. 5A-C are mimetic diagrams illustrating the pattern forming method according to the embodiment of the present invention.

FIG. 6 is a mimetic diagram illustrating a case where droplets are arranged on a substrate based on predetermined bit map data.

FIG. 7 is a mimetic diagram illustrating a case where droplets are arranged on a substrate based on predetermined bit map data.

FIG. 8 is a mimetic diagram illustrating a case where droplets are arranged on a substrate based on predetermined bit map data.

FIG. 9 is a mimetic diagram illustrating a case where droplets are arranged on a substrate based on predetermined bit map data.

FIG. 10 is a mimetic diagram illustrating a case where droplets are arranged on a substrate based on predetermined bit map data.

FIG. 11 is a mimetic diagram illustrating a case where droplets are arranged on a substrate based on predetermined bit map data.

FIG. 12 is a schematic perspective view illustrating a pattern forming apparatus according to an embodiment of the present invention.

FIG. 13 illustrates an electro-optical device according to an embodiment of the present invention and is an exploded perspective view illustrating an example to which a plasma display device is applied.

FIG. 14 illustrates an electro-optical device according to an embodiment of the present invention and is a plan view illustrating an example to which a liquid crystal display device is applied.

FIG. 15 shows another embodiment of the liquid crystal display device.

FIG. 16 is a view illustrating a field emission display (FED).

FIG. 17 illustrates an embodiment of an electronic apparatus according to the present invention.

### DETAILED DESCRIPTION

Pattern Forming Method

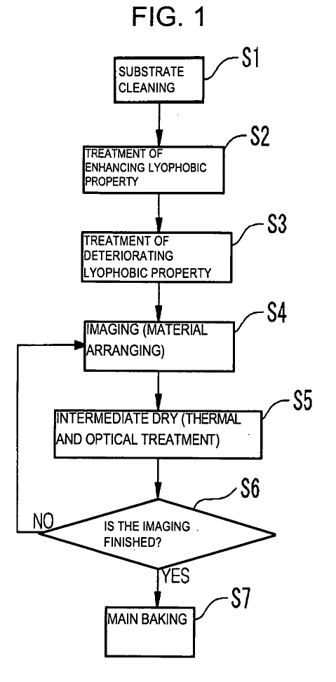

Hereinafter, a pattern forming method according to the present invention will be described with reference to the accompanying drawings. FIG. 1 is a flowchart of a pattern forming method according to an embodiment of the present invention.

Here, in the present embodiment, a case where a conductive film wiring pattern is formed on a substrate will be described.

In FIG. 1, the pattern forming method according to the present embodiment comprises a step (step S1) of cleaning a substrate on which droplets of a liquid material are arranged, using a predetermined solvent; a step (step S2) of performing lyophobic treatment that constitutes a part of a surface treatment step of the substrate; a step (step S3) of performing lyophobic property controlling treatment that constitutes a part of the surface treatment step of adjusting a lyophobic property of the surface of the substrate on which lyophobic treatment is performed; a material arrangement step (step S4) of arranging droplets of the liquid material including a material for forming conductive film wiring, on the substrate on which the surface treatment step is performed, based on a droplet discharge method and drawing (forming) a film pattern; an intermediate drying step (step S5) including heat/light treatment for removing at least a part of a solvent component of the liquid material arranged on the substrate; and a baking step (step S7) of baking the substrate on which a predetermined pattern is drawn. The pattern forming method further comprises a step (step S6) of determining whether a predetermined pattern drawing has been completed after the intermediate drying step, and if the pattern drawing has been completed, the baking step is performed, and if the pattern drawing has not been completed, the material arrangement step is performed.

Next, the material arranging step (step S4) based on the droplet discharge method will be described, which is a part characterizing the present invention.

The material arrangement step according to the present embodiment is a step of discharging droplets of a liquid material including a material for forming conductive film wiring onto a substrate from a droplet discharge head of a droplet discharge device so that a plurality of linear film pattern (wiring pattern) can be formed on the substrate. The liquid material is a liquid material in which conductive particles, such as metal, as the material for forming the conductive film wiring are dispersed in a dispersion medium. In the following description, a case where first, second and third film patterns (line-shaped patterns) W1, W2 and W3 are formed on the substrate 11 will be explained.

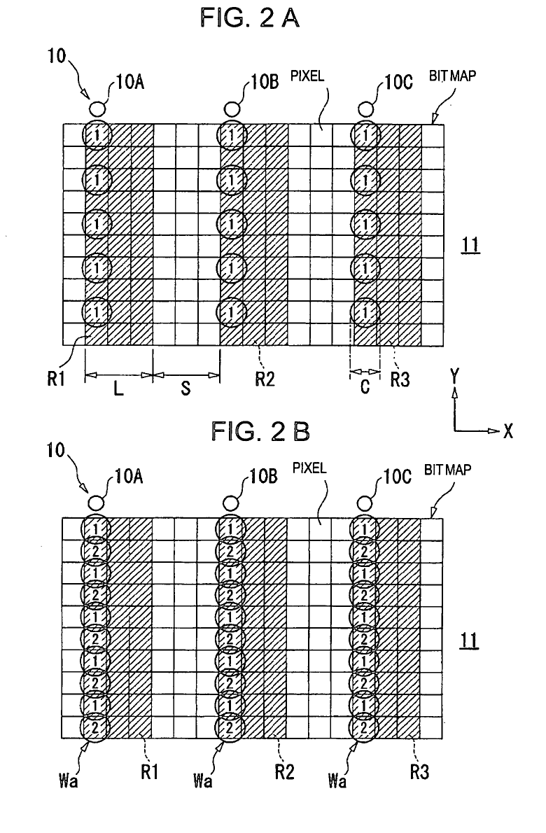

FIGS. 2, 3 and 4 are diagrams illustrating an example of an order in which the droplets are arranged on the substrate 11 in this embodiment. In the drawings, a bit map having pixels that are a plurality of unit areas of a lattice shape in which the droplets of a liquid material should be arranged is set on the substrate 11. Here, each pixel is formed in a square shape. First, second and third pattern forming areas R1, R2, and R3 for forming first, second and third film patterns W1, W2 and W3, respectively, are defined corresponding to predetermined pixels of the plurality of pixels. The plural pattern forming areas R1, R2, and R3 are arranged in an X-axis direction. In FIGS. 2 to 4, the pattern forming areas R1, R2, and R3 are denoted by a gray color.

The droplets of a liquid material discharged from a first discharge nozzle 10A of a plurality of discharge nozzles provided in a discharge head 10 of a droplet discharge device are arranged in the first pattern forming area R1 on the substrate 11. Similarly, the droplets of a liquid material discharged from a second discharge nozzle 10B and a third discharge nozzle 10C of the plurality of discharge nozzles provided in the discharge head 10 of the droplet discharge device are arranged in the second pattern forming areas R2 and the third pattern forming area R3 on the substrate 11, respectively. That is, the discharge nozzles (discharge portions) 10A, 10B, and 10C are provided corresponding to the first, second and third pattern forming areas R1, R2, and R3, respectively. Then, the droplet discharge head 10 sequentially arranges the plurality of droplets in the plurality of pixel positions of the plurality of defined pattern forming areas R1, R2, and R3, respectively.

Furthermore, in each of the first, second and third pattern forming areas R1, R2, and R3, the first, second and third film patterns W1, W2, W3 to be formed in the pattern forming areas R1, R2, and R3 are formed from a first side pattern Wa that is one side (−X side) in the line-width direction, and then a second side pattern Wb that is the other side (+X side) is formed. After forming the first and second side patterns Wa, Wb, a central pattern Wc that is a central portion in the line-width direction is formed.

In this embodiment, the respective pattern forming areas R1 to R3 as well as the respective film patterns (line-shaped patterns) W1 to W3 have the same line width L, and the line width L is set to a size corresponding to three pixels. Respective space portions between the patterns are set to the same width S, and the width S is set to a size corresponding to three pixels. A nozzle pitch that is a gap between the discharge nozzles 10A to 10C is set to a size corresponding to six pixels.

In the following description, the droplet discharge head 10 having the discharge nozzle 10A, 10B, 10C discharges the droplets while scanning the substrate 11 in a Y-axis direction. In the description with reference to FIGS. 2 to 4, the droplets arranged at the first time of scan are denoted by “1”, and the droplets arranged at second, third, . . . , n-th scans are denoted by “2”, “3”, . . . , “n”, respectively.

As shown in FIG. 2(a), at the first scanning, in order to form the first side pattern Wa in each of the first, second and third pattern forming areas R1, R2, R3, the droplets discharged from the first, second and third discharge nozzles 10A, 10B, 10C are simultaneously arranged every two pixels of first side pattern forming areas. Here, the droplets to be arranged on the substrate 11 land on the substrate 11, and flow around on the substrate 11. That is, as shown by a circle in FIG. 2(a), the droplets landing at the substrate 11 flow around to have a diameter C larger than a size of one pixel. Here, since the droplets are arranged with a predetermined gap (corresponding to one pixel) in the Y-axis direction, the droplets arranged on the substrate 11 do not overlap each other. As a result, the liquid material can be prevented from being arranged excessively on the substrate 11 in the Y-axis direction, so that it is possible to prevent generation of bulges.

In addition, in FIG. 2(a), the droplets are arranged on the substrate 11 not to overlap with one another, but the droplets may be arranged to slightly overlap with one another. In addition, the droplets are discharged by opening one pixel, but the droplets may be discharged by opening intervals of two or more pixels. In this case, the number of scanning and arranging operations (discharge operations) of the droplet discharge head 10 on the substrate 11 is increased so that an interval between the droplets on the substrate is interpolated.

In addition, since the surface of the substrate 11 is treated in advance to have a desired lyophobic property by steps S2 and S3, the excessive spread of the droplets arranged on the substrate 11 is suppressed. Therefore, a pattern shape can be surely controlled in a good state, and the thickness of a thin film can be easily increased.

FIG. 2(b) is a mimetic diagram showing a case where droplets are discharged to the substrate 11 from the droplet discharge head 10 by the second scanning. In addition, in FIG. 2(b), “2” is given to the droplets discharged during the second scanning. During the second scanning, the droplets are simultaneously discharged from the respective discharge nozzles 10A, 10B, 10C to interpolate an interval between the droplets “1” discharged during the first scanning. Then, the droplets are continuously connected each other by the first and second scans and the arrangement operation, so that the first side patterns Wa are formed in the first, second and third pattern forming areas R1, R2, R3. Here, the droplets “2” are diffused at the time of landing in the substrate 11, so that a part of the droplets “2” and a part of the droplets “1” previously arranged on the substrate 11 overlap each other. Specifically, a part of the droplets “2” overlap the droplets “1”.

Here, after the droplets to form the first side pattern Wa are arranged on the substrate 11, in order to remove a dispersion medium, intermediate drying (step S5) can be performed, if necessary.

The intermediate drying may be light treatment using lamp annealing other than general heat treatment using a heating apparatus, such as a hot plate, an electric furnace, or a hot blast generator.

Next, the droplet discharge head 10 is moved relative to the substrate 11 in an X-axis direction by the distance of two pixels. Here, the droplet discharge head 10 makes a stepwise movement with respect to the substrate 11 in the +X-axis direction by the distance of two pixels. Accordingly, the discharge nozzles 10A, 10B, 10C are moved.

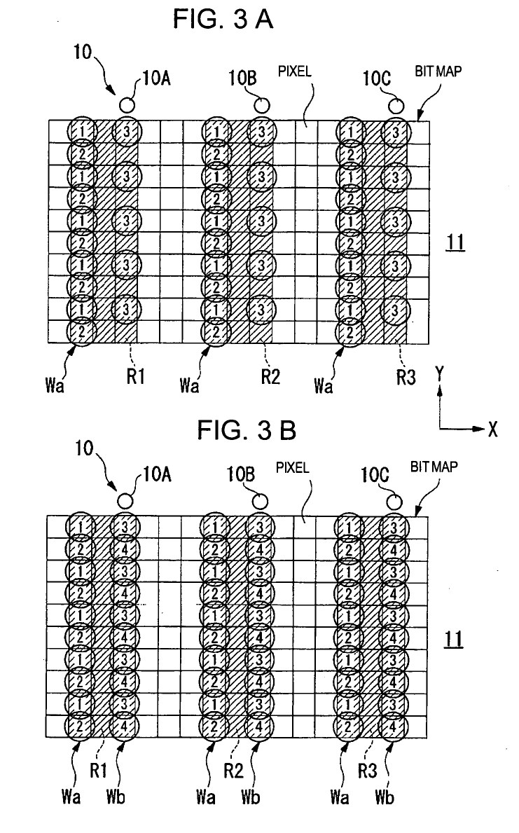

Then, the droplet discharge head 10 performs third scanning. As a result, as shown in FIG. 3(a), in order to form the second side pattern Wb constituting a part of each of the film patterns W1, W2, and W3, droplets “3” are simultaneously arranged on the substrate 11 from the respective discharge nozzles 10A, 10B, and 10C by opening one pixel in the X-axis direction. Here, the droplets “3” are arranged by opening one pixel in the Y-axis direction.

FIG. 3(b) is a mimetic diagram showing a case where droplets are discharged to the substrate 11 from the droplet discharge head 10 by fourth scanning. In addition, in FIG. 3(b), “4” is given to the droplets discharged during the fourth scanning. During the fourth scanning, the droplets are simultaneously discharged from the respective discharge nozzles 10A, 10B, 10C to interpolate (fill) an interval between the droplets “3” discharged during the third scanning. By performing the third and fourth scanning and discharge operations, the droplets are continuously discharged, and the second side pattern Wb of the pattern forming regions R1, R2, R3 is formed. Here, a part of the droplets “4” and a part of the droplets “3” previously arranged on the substrate 11 overlap each other. Specifically, a part of the droplets “4” overlap the droplets “3”.

Here, after the droplets to form the second side pattern Wb are arranged on the substrate 11, in order to remove a dispersion medium, intermediate drying can be performed, if necessary.

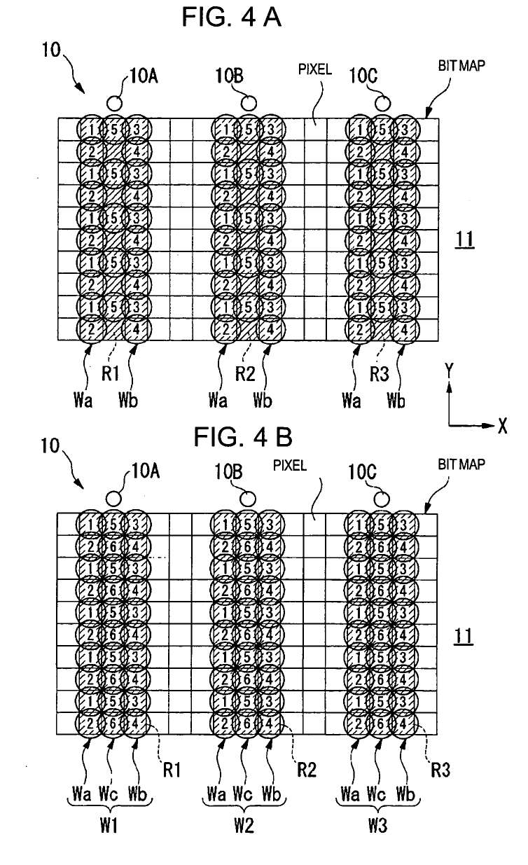

Next, the droplet discharge head 10 is stepwise moved by one pixel in the −X direction with respect to the substrate, and the discharge nozzles 10A, 10B, 10C are thus moved by one pixel in the −X direction. Then, the droplet discharge head 10 performs the fifth scan. Accordingly, as shown in FIG. 4(a), the droplets “5” for forming the central pattern Wc constituting a part of each film pattern W1, W2, W3 are simultaneously arranged on the substrate. Here, the droplets “5” are arranged every one pixel (every other pixel) in the Y-axis direction. Here, a part of the droplets “5” and a part of the droplets “1” and “3” having been previously arranged on the substrate 11 overlap each other. Specifically, a part of the droplets “5” overlap the droplets “1” and “3”.

FIG. 4(b) is a mimetic diagram showing a case where droplets are discharged to the substrate 11 from the droplet discharge head 10 by sixth scanning. In addition, in FIG. 4(b), “6” is given to the droplets discharged during the sixth scanning. During the sixth scanning, the droplets are simultaneously arranged from the respective discharge nozzles 10A, 10B, 10C to interpolate (fill) an interval between the droplets “5” discharged during the fifth scanning. Then, by performing the fifth and sixth scanning and discharge operations, the droplets are continuously discharged, and the central pattern Wc of the pattern forming regions R1, R2, R3 is formed. Here, a part of the droplets “6” and a part of the droplets “5” previously arranged on the substrate 11 overlap each other. Specifically, a part of the droplets “6” overlap the droplets “5”. Furthermore, a part of the droplets “6” overlap the droplets “2” and “4” previously arranged on the substrate 11.

In this way, the film patterns W1, W2, W3 are formed in the pattern forming areas R1, R2, R3, respectively.

As described above, when the film patterns W1, W2, W3 having substantially the same shape are formed by sequentially arranging a plurality of droplets in the pattern forming areas R1, R2, R3, the arrangement order of arranging the droplets is set to be equal in a plurality of pixels of the pattern forming areas R1, R2, R3. Therefore, even when the droplets “1” to “6” are arranged to overlap a part thereof, the overlapping shape is equal to each other in the film patterns W1, W2, W3, so that the appearances of the film patterns W1, W2, W3 can be made to be equal. Therefore, the lack of uniformity in appearance between the film patterns W1, W2, W3 can be prevented from being generated.

Since the arrangement order of the droplets is set to be substantially equal in the film patterns W1, W2, W3, the arrangements (overlapped states between the droplets) of the droplets in the film patterns W1, W2, W3 are equal each other, so that the lack of uniformity in appearance can be prevented.

Furthermore, since the overlapping states between the droplets in the film patterns W1, W2, W3 are equal each other, thickness distribution in the film patterns can be set to be substantially equal. As a result, when the film patterns are a repeated pattern which is repeated in the in-plane direction of the substrate, specifically, when the film patterns are, for example, patterns which are arranged corresponding to the pixels of a display device, the pixels have the same thickness distribution. Therefore, the same function is obtained from the positions in the in-plane direction of the substrate.

Since the first and second side patterns Wa, Wb are first formed and then the droplets “5” and “6” for forming the central patterns Wc are arranged to fill the gaps therebetween, the film patterns W1, W2, W3 can be formed to be uniform in the line width. That is, when the central patterns Wc are first formed on the substrate 11 and then the droplets “1”, “2”, “3” and “4” for forming the side patterns Wa, Wb are arranged, a phenomenon that the droplets are drawn toward the central patterns Wc previously formed on the substrate 11 occurs, so that it is difficult to control the line width of the film patterns W1, W2, W3. However, in this embodiment, since the side patterns Wa, Wb are first formed on the substrate 11 and then the droplets “5” and “6” for forming the central patterns Wc are formed to fill the gaps therebetween, it is possible to control the line width of the film patterns W1, W2, W3 with a high accuracy.

The side patterns Wa, Wb may be formed after the central patterns Wc are formed. In this case, by allowing the arrangement order of the droplets to be equal in the film patterns W1 to W3, the lack of uniformity in appearance between the patterns can be prevented from occurring.

In this embodiment, the discharge nozzles are arranged to correspond to the pattern forming areas (film patterns), respectively, and the film patterns are formed out of the droplets discharged from the discharge nozzles. Accordingly, in order to arrange the discharge nozzles corresponding to the pattern forming areas as in this embodiment, the following equation should be satisfied, Np=S+(n×L), where the number of pixels (or the line width) in the X-axis direction of the pattern forming areas (film patterns) is S, the number of pixels (or the line width) in the X-axis direction of the space portions is L, and the nozzle pitch that is an arrangement gap of the discharge nozzle is Np.

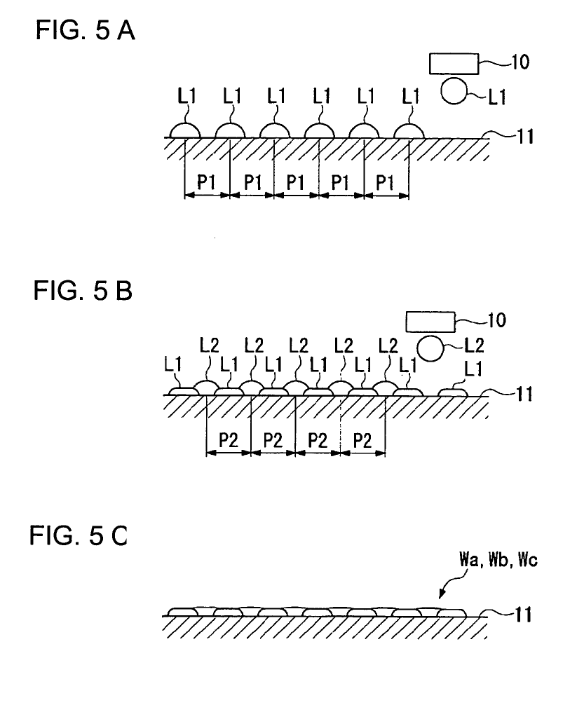

FIG. 5 is a side view schematically illustrating the order of forming the side patterns Wa, Wb and the central pattern Wc having a line shape.

First, as shown in FIG. 5(a), droplets L1 discharged through a droplet discharge head 10 are sequentially arranged on a substrate 11 at predetermined intervals. In other words, the droplet discharge head 10 arranges the droplets L1 on the substrate 11 so as not to overlap with one another. In the present embodiment, an arrangement pitch P1 of the droplets L1 is set to be larger than the diameter of the droplets L1 immediately after being arranged on the substrate 11. As a result, the droplets L1 immediately after being arranged on the substrate 11 are prevented from overlapping with one another (from contacting one another), and the droplets L1 are combined with one another and are prevented from spreading on the substrate 11. In addition, the arrangement pitch P1 of the droplet L1 is set to be less than twice the diameter of the droplet L1 immediately after being arranged on the substrate 11.

Here, after the droplets L1 are arranged on the substrate 11, in order to remove a dispersion medium, intermediate drying (step S5) may be performed, if necessary. As described above, the intermediate drying may be light treatment using lamp annealing other than general heat treatment using a heating apparatus, such as a hot plate, an electric furnace, and a hot blast generator.

Next, as shown in FIG. 5(b), the arrangement operation of the above-described droplets is repeatedly performed. In other words, as in the previous step as shown in FIG. 5(a), the liquid material is discharged as droplets L2 from the droplet discharge head 10, and the droplets L2 are arranged on the substrate 11 at predetermined intervals. In this case, the volume of the droplets L2 (the amount of the liquid material per one droplet) and an arrangement pitch P2 thereof are the same as those of the previous droplets L1. The arrangement position of the droplets L2 is shifted by a ½ pitch from the previous droplets L1, and the droplets L2 are arranged at intermediate positions of the previous droplets L1 arranged on the substrate 11.

As described above, the arrangement pitch P1 of the droplets L1 on the substrate 11 is larger than the diameter of the droplets L1 immediately after being arranged on the substrate 11 and is less than twice the diameter. Therefore, the droplets L2 are arranged in the intermediate position of the droplets L1 so that parts of the droplets L2 overlaps with the droplets L1, and a gap between the droplets L1 is filled with the overlapped droplets L2. In this case, the present droplets L2 and the previous droplets L1 contact one another. However, since the dispersion medium in the droplets L1 is completely or somewhat removed, there is less probability that the previous droplets and the present droplets are combined with one another and are spread on the substrate 11.

In addition, in FIG. 5(b), a position in which the arrangement of the droplets L2 begins, is at the same side (left side of FIG. 5(a)) as that of the previous step, but may be at a reverse side (right side). Discharge of droplets is performed during movement in each direction of a reciprocating operation so that the distance of movement of the droplet discharge head 10 relative to the substrate 11 from can be reduced.

After the droplets L2 are arranged on the substrate 11, in order to remove the dispersion medium, as in the previous step, intermediate drying can be performed, if necessary.

A series of such arrangement operations of droplets are repeatedly performed so that a gap between droplets arranged on the substrate 11 is filled, and as shown in FIG. 5(c), linear and continuous central pattern Wc and side patterns Wa and Wb are formed on the substrate 11. In this case, the number of repetitions of the arrangement operation of the droplets is increased so that the droplets sequentially overlap with one another on the substrate 11, and the layer thickness of the linear patterns Wa, Wb, and Wc, that is, the height (thickness) of the patterns from the surface of the substrate 11 is increased.

The height (thickness) of the linear patterns Wa, Wb, and Wc is set according to a desired layer thickness required in a final film pattern, and the number of repetitions of the arrangement operation of the droplets is set according to the set layer thickness.

In addition, the method of forming linear patterns is not limited to those shown in FIGS. 5(a) to 5(c).

For example, the arrangement pitch of droplets or the amount of shifting during repetition can be set arbitrarily, and the arrangement pitch on a substrate P of droplets when forming the patterns Wa, Wb, and Wc may be set to different values. For example, if the droplet pitch in forming the central patterns Wc is P1, the droplet pitch in forming the side patterns Wa, Wb may be set to a pitch larger than P1. Of course, it may be set to a pitch smaller than P1. Further, the volume of the droplets in forming the patterns Wa, Wb, Wc may be set to another value. Alternatively, the droplet discharge atmosphere (temperature or humidity) which is an atmosphere in which the substrate 11 or the droplet discharge head 10 is arranged may be set to another condition.

In this embodiment, the line-shaped patterns Wa, Wb, Wc are formed one by one, but a plurality of patterns may be formed simultaneously (for example, two patterns Wb, Wc may be formed simultaneously). Since the total number of dry processes may be different between a case where the plurality of patterns Wa, Wb, Wc are formed one by one and a case where the plurality of patterns are formed simultaneously, the dry condition should be determined not to damage the lyophobic property of the substrate 11.

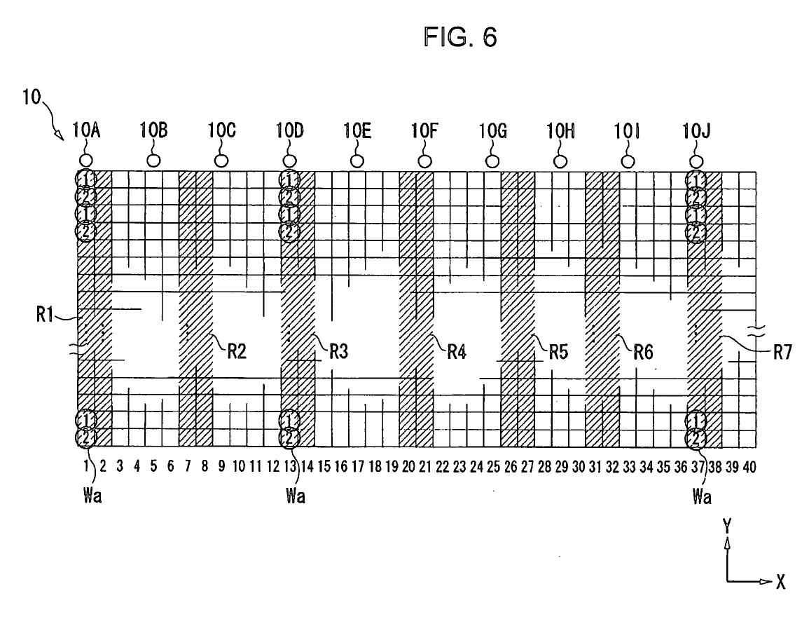

Next, another embodiment of the pattern forming method will be described with reference to FIGS. 6 to 11. Here, it is supposed that there are ten discharge nozzles 10A to 10J, and the nozzle pitch is set to correspond to four pixels. In other words, the number of corresponding lattices (the number of corresponding pixels) in the X-axis direction of each discharge nozzle is four. That is, a range on a substrate in which each discharge nozzle can arrange the droplets (that is, an area in which a pattern can be formed by one discharge nozzle) corresponds to four pixels (four columns) in the X-axis direction. For example, the first discharge nozzle 10A can arrange the droplets in the range of the first to fourth pixel lines in FIG. 6, and the second discharge nozzle 10B can arrange the droplets in the range of the fifth to eighth pixel lines. Similarly, the discharge nozzle 10C can arrange the droplets in the range of pixels in the ninth to twelfth columns, the discharge nozzle 10D can arrange the droplets in the range of pixels in the thirteenth to sixteenth columns, . . . , the discharge nozzle 10H can arrange the droplets in the range of pixels in the twenty-ninth to thirty-second columns, the discharge nozzle 101 can arrange the droplets in the range of pixels in the thirty-third to thirty-sixth columns, and the discharge nozzle 10J can arrange the droplets in the range of pixels in the thirty-seventh to fortieth columns. In this embodiment, the wiring patterns (film patterns) W1 to W7 having a line width corresponding to two pixels as a designed value are formed. That is, the pattern forming areas R1 to R7 in which the wiring patterns should be formed are defined as areas denoted by a gray color in FIG. 6.

As shown in FIG. 6, out of the widths of the space portions between the pattern forming areas R1 to R7 (that is, the film patterns W1 to W7), a width of the space portion between the patter forming area R1 and R2 corresponds to four pixels, and a width of the space portion between the pattern forming areas R2 and R3 corresponds to four pixels. Similarly, a width of the space portion between the pattern forming areas R3 and R4 corresponds to five pixels, a width of the space portion between the pattern forming areas R4 and R5 corresponds to four pixels, a width of the space portion between the pattern forming areas R5 and R6 corresponds to three pixels, and a width of the space portion between the pattern forming areas R6 and R7 corresponds to four pixels. In this way, the wiring pitches (that is, the space portions) that are arrangement gaps of the wiring patterns are set to be unequal.

In this embodiment, for each film pattern having a line width corresponding to two pixels, the first side pattern Wa at one side (−X side) is first formed, and then the second side pattern Wb at the other side (+X side) is formed.

In FIG. 6, the discharge nozzle 10A is positioned at the first side pattern forming area (that is, first column) of the pattern forming area R1, the discharge nozzle 10D is positioned at the first side pattern forming area (that is, thirteenth column) of the pattern forming area R3, and the discharge nozzle 10J is positioned at the first side pattern forming area (that is, thirty-seventh column) of the pattern forming area R7. Therefore, the droplets can be arranged in the pattern forming areas R1, R3, R7. On the other hand, no discharge nozzle is positioned at the pattern forming areas R2, R5, R6. Therefore, the pattern forming areas R2, R5, R6 are in the arrangement idle condition of droplets. Although the discharge nozzle 10F is positioned at the pattern forming area R4, the discharge nozzle 10F is positioned at the second side pattern forming area (twenty-first column), not at the first side pattern forming area (twentieth column). Therefore, the pattern forming area R4 is in the arrangement idle condition of droplets.

Then, in the order similar to the order described with reference to FIGS. 2 to 5, the droplet discharge head 10 scans the substrate 11, and the droplets are simultaneously discharged from the discharge nozzles 10A, 10D, 10J. By the first and second scans, as indicated by “1” and “2” in FIG. 6, the droplets are simultaneously arranged in the pattern forming areas R1, R3, R7. As a result, the first side patterns Wa are formed in the pattern forming areas R1, R3, R7.

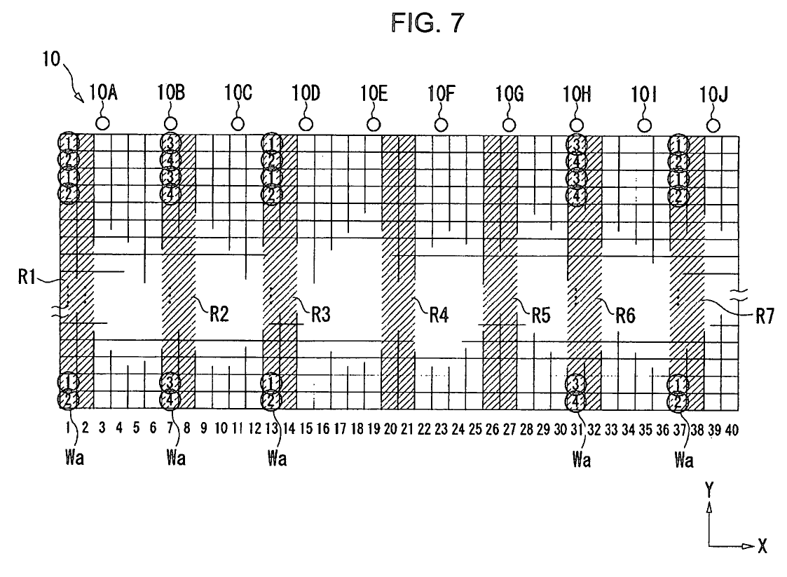

Next, as shown in FIG. 7, the droplet discharge head 10 is stepwise moved in the X-axis direction. Here, it is supposed that the droplet discharge head 10 is stepwise moved by two pixels in the +X direction. Then, the discharge nozzles 10A to 10J are moved with movement of the droplet discharge head 10.

In FIG. 7, the discharge nozzle 10B is positioned at the first side pattern forming area (that is, seventh column) of the pattern forming area R2, and the discharge nozzle 10H is positioned at the first side pattern forming area (that is, thirty-first column) of the pattern forming area R6. Therefore, the droplets can be arranged in the pattern forming areas R2, R6. On the other hand, no discharge nozzle is positioned at the pattern forming areas R1, R3, R4, and R7. Therefore, the pattern forming areas R1, R3, R4, R7 are in the arrangement idle condition of droplets. Although the discharge nozzle 10G is positioned at the pattern forming area R5, the discharge nozzle 10G is positioned at the second side pattern forming area (twenty-seventh column), not at the first side pattern forming area (twenty-sixth column). Therefore, the pattern forming area R5 is in the arrangement idle condition of droplets.

Then, the droplet discharge head 10 scans the substrate 11, and thus the droplets are simultaneously discharged from the discharge nozzles 10B, 10H. By the third and fourth scans, as indicated by “3” and “4” in FIG. 7, the droplets are simultaneously arranged in the pattern forming areas R2, R6. As a result, the first side patterns Wa are formed in the pattern forming area R2, R6.

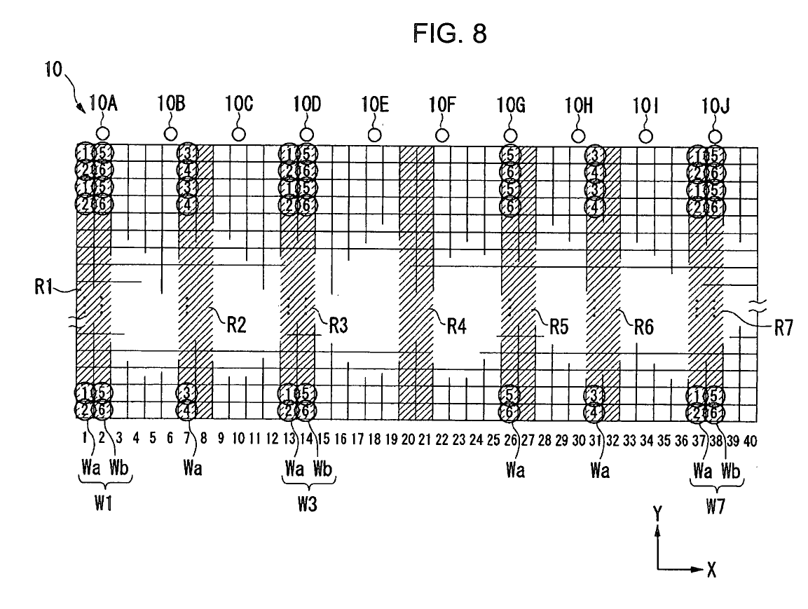

Next, as shown in FIG. 8, the droplet discharge head 10 is stepwise moved in the X-axis direction. Here, it is supposed that the droplet discharge head 10 is stepwise moved by one pixel in the −X direction. In FIG. 8, the discharge nozzle 10A is positioned at the second side pattern forming area (second column) of the pattern forming area R1, the discharge nozzle 10D is positioned at the second side pattern forming area (fourteenth column) of the pattern forming area R3, the discharge nozzle 10G is positioned at the first side pattern forming area (twenty-sixth column) of the pattern forming area R5, and the discharge nozzle 10J is positioned at the second side pattern forming area (thirty-eighth column) of the pattern forming area R7. On the other hand, no discharge nozzle is positioned at the pattern forming areas R2, R4, R6. Therefore, the pattern forming areas R2, R4, R6 are in the arrangement idle condition of droplets.

Then, the droplet discharge head 10 scans the substrate 11, and thus the droplets are simultaneously discharged form the discharge nozzles 10A, 10D, 10G, 10J. By the fifth and sixth scans, as indicated by “5” and “6” in FIG. 8, the droplets are simultaneously arranged in the pattern forming areas R1, R3, R5, and R7. As a result, the second side patterns Wb are formed in the pattern forming areas R1, R3, R7, and the first side pattern Wa is formed in the pattern forming area R5. The film patterns W1, W3, W7 are completed in the pattern forming areas R1, R3, R7. Here, in the completed film patterns W1, W3, W7, the first side patterns Wa are first formed, and the second side patterns Wb are then formed. The arrangement order of the droplets is equal in the pattern forming areas R1, R3, R7.

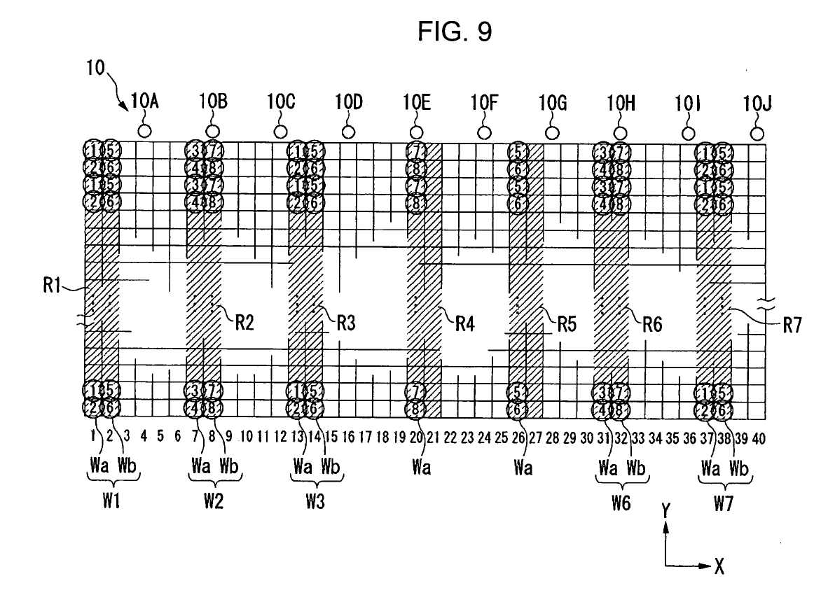

Next, as shown in FIG. 9, the droplet discharge head 10 is stepwise moved in the X-axis direction. Here, it is supposed that the droplet discharge head 10 is stepwise moved by two pixels in the +X direction. In FIG. 9, the discharge nozzle 10B is positioned at the second side pattern forming area (eighth column) of the pattern forming area R2, the discharge nozzle 10E is positioned at the first side pattern forming area (twentieth column) of the pattern forming area R4, and the discharge nozzle 10H is positioned at the second side pattern forming area (thirty-second column) of the pattern forming area R6. On the other hand, no discharge nozzle is positioned at the pattern forming areas R1, R3, R5, and R7. Therefore, the pattern forming areas R1, R3, R5, R7 are in the arrangement idle condition of droplets.

Then, the droplet discharge head 10 scans the substrate 11, and the droplets are simultaneously discharged from the discharge nozzles 10B, 10E, and 10H. By the seventh and eighth scans, as indicated by “7” and “8” in FIG. 9, the droplets are simultaneously arranged in the pattern forming areas R2, R4, R6. As a result, the first side pattern Wa is formed in the pattern forming area R4, and the second side patterns Wb are formed in the pattern forming areas R2, R6, so that the film patterns W2, W6 are completed in the pattern forming areas R2, R6. Here, in the completed film pattern W2, W6, the first side patterns Wa are first formed, and the second side patterns Wb are then formed, so that the arrangement order of the droplets is equal in the film patterns W2, W6, and the arrangement order of the droplets is also equal to that of the film patterns W1, W3, W7 which have been already completed.

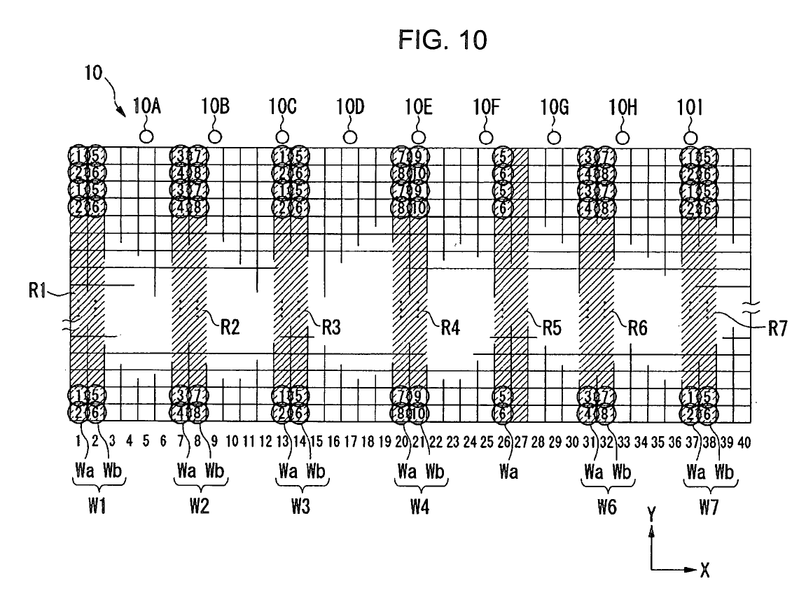

Next, as shown in FIG. 10, the droplet discharge head 10 is stepwise moved in the X direction. Here, it is supposed that the droplet discharge head 10 is stepwise moved by one pixel in the +X direction. In FIG. 10, the discharge nozzle 10E is positioned at the second side pattern forming area (twenty-first column) of the pattern forming area R4. On the other hand, no discharge nozzle is positioned at the pattern forming areas R1, R2, R5, and R6. Therefore, the pattern forming areas R1, R2, R5, R6 are in the arrangement idle condition of the droplets. Although the discharge nozzles 10C, 10I are positioned at the first side pattern forming areas (twentieth column and thirty-seventh column) of the pattern forming areas R3 and R7, respectively, the droplets “1” and “2” are already arranged in the areas, so that the pattern forming areas R3, R7 are in the arrangement idle condition of the droplets.

Then, the droplet discharge head 10 scans the substrate 11, and the droplets are discharged from the discharge nozzle 10E. By the ninth and tenth scans, as indicated by “9” and “10” in FIG. 10, the droplets are arranged in the pattern forming area R4. As a result, the second side pattern Wb is formed in the pattern forming area R4, so that the film pattern W4 is completed. In the film pattern W4, the first side pattern Wa is first formed, and then the second side pattern Wb is formed, so that the arrangement order of the droplets is equal to that of the film patterns W1, W2, W3, W6, and W7 which have been already completed.

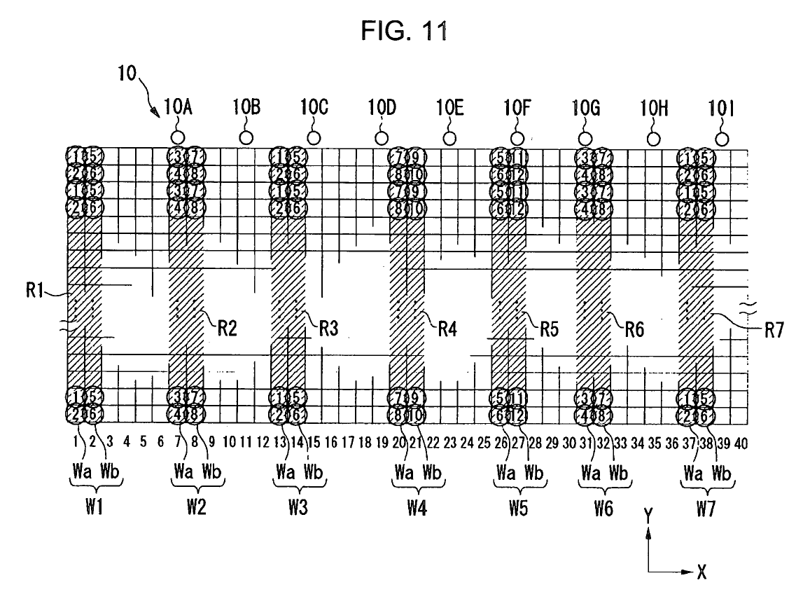

Next, as shown in FIG. 11, the droplet discharge head 10 is stepwise moved in the X-axis direction. Here, it is supposed that the droplet discharge head 10 is stepwise moved by one pixel in the +X direction. In FIG. 11, the discharge nozzle 10F is positioned at the second side pattern forming area (twenty-seventh column) of the pattern forming area R5.

The droplet discharge head 10 scans the substrate 11, and the droplets are discharged from the discharge nozzle 10F. By the eleventh and twelfth scans, as indicated by “11” and “12” in FIG. 11, the droplets are arranged in the pattern forming area R5. As a result, the second side pattern Wb is formed in the pattern forming area R5, so that the film pattern W5 is completed. In the film pattern W5, the first side pattern Wa is first formed, and the second side pattern Wb is then formed, so that the arrangement order of the droplets is equal to that of the film patterns W1, W2, W3, W4, W6, and W7 which have been already completed.

In this way, the first to seventh film patterns W1 to W7 are formed. As in this embodiment, even if the nozzle pitch and the wiring pitch are not equal, the arrangement order of the droplets can be set to be equal in the pattern forming areas R1 to R7 and the patterns can be formed efficiently, by arranging the droplets while moving the droplet discharge head 10 having a plurality of discharge nozzles in a direction (X-axis direction) in which the pattern forming areas R1 to R7 are arranged.

In the pattern forming method shown in FIGS. 6 to 9, the droplets are arranged when the following relationships are established. In the following description, it is supposed that when the instruction previously set for the pixels (columns) on the bit map is “0”, the droplets are not arranged, and when the instruction is “1”, the droplets are arranged. It is also supposed that the columns (first, fifth, . . . , thirty-seventh columns) in which the remainder obtained by diving the number n (1 to 40) of each column of the bit map by the number of pixels 4 corresponding to the discharge nozzle is 1 are N1, the columns (second, sixth, . . . , thirty eighth columns) in which the remainder is 2 are N2, the columns (third, seventh, . . . , thirty-ninth columns) in which the remainder is 3 are N3, and the columns (fourth, eighth, . . . , fortieth columns) in which the remainder is 0 are N0. That is, the discharge nozzles are positioned at the N1 columns in FIG. 6, the discharge nozzles are positioned at the N2 columns in FIG. 8, the discharge nozzles are positioned at the N3 columns in FIG. 7, and the discharge nozzles are positioned at the N4 columns in FIG. 9.

In the N1 columns, the relationsips a(n−1)=0, a(n)=1 are established, the relationsips a(n)=1, b(n)=1, b(n−1)=0, b(n)=1 are established in the N2 columns, the relationsips b(n)=1, c(n)=1, c(n−1)=0, c(n)=1 are established in the N3 columns, and the relationsips c(n)=1, d(n)=1, d(n−1)=0, d(n)=1 are established in the N4 columns. Here, a is a function (output data indicating whether the droplets are discharged or not) for the first pixel (column) of four pixels corresponding to each discharge nozzle, and b, c and d are functions (output data indicating whether the droplets should be discharged or not) for the second, third and fourth pixels (columns), respectively.

Describing N1 with reference to FIG. 6, for example, in a case of n=13, a (13−1)=0, that is, an instruction that the droplets should not be arranged in the twelfth column, is set in advance in the bit map data, and a (13)=1, that is, an instruction that the droplets should be arranged in the thirteenth column is set in advance, but when a control unit recognizes that the instruction and the relationships coincide, the control unit to be described later for controlling the droplet discharge head 10 allows the droplets to be arranged in the thirteenth column (that is, the column corresponding to the first side pattern Wa) through the discharge nozzle 10D. On the other hand, for example, in a case of n=21, since a (20)=1 and a (21)=1 do not coincide with the relationships, the control unit allows the droplets to be arranged in the twenty-first column. Similarly, for example, in a case of n=9, since a (8)=1 and a (9)=0 do not coincide with the relationship, the control unit does not allow the droplets to be arranged in the ninth column.

Describing N2 with reference to FIG. 8, for example, in a case of n=14, the previous history of a (13)=1, that is, the instruction that the droplets should be arranged in the thirteenth column, is set in advance, and b (14)=1, that is, the instruction that the droplets should be arranged in the fourteenth column, is set in advance. The control unit recognizing that the instruction and the relationships coincide allows the droplets to be arranged in the fourteenth column (that is, the column corresponding to the second side pattern Wb) through the discharge nozzle 10D. In a case of n=26, since b (25)=0 and b (26)=1 coincide with the relationships, the control unit allows the droplets to be arranged in the twenty-sixth column through the discharge nozzle 10G. On the other hand, for example, in a case of n=22, since b (21)=1 and b (22)=0 do not satisfy the relationships, the control unit does not allow the droplets to be arranged in the twenty-second column.

Describing N3 with reference to FIG. 7, for example, in a case of n=7, since c (6)=0 and c (7)=1 satisfy the relationships, the control unit allows the droplets to be arranged in the seventh column through the discharge nozzle 10B. On the other hand, for example, in a case of n=19, since c (18)=0 and c (19)=0 do not satisfy the relationships, the control unit does not allow the droplets to be arranged in the nineteenth column.

Describing N4 with reference to FIG. 9, for example, in a case of n=8, the previous history of c (7)=1, that is, the instruction that the droplets should be arranged in the seventh column, is set in advance, and d (8)=1, that is, the instruction that the droplets should be arranged in the eighth column, is set in advance. The control unit recognizing that the instruction and the relationships coincide allows the droplets to be arranged in the eighth column through the discharge nozzle 10B. On the other hand, in a case of n=20, since c (19)=0 and d (20)=1 coincide with the relationships, the control unit allows the droplets to be arranged in the twentieth column through the discharge nozzle 10E. On the other hand, for example, in a case of n=28, since d (27)=1 and d (28)=0 do not satisfy the relationships, the control unit does not allow the droplets to be arranged in the twenty-eighth column.

In addition, in the present embodiment, a variety of materials, such as a glass, a quartz glass, a Si wafer, a plastic film, and a metallic plate may be used as a substrate for conductive film wiring. In addition, a semiconductor film, a metallic film, a dielectric film, or an organic film may be formed as a base layer on the surface of the substrate formed of the variety of materials.

In the present embodiment, a dispersion solution (liquid material) in which conductive particles are dispersed in a dispersion medium, is used as the liquid material for conductive film wiring, and it does not matter whether the dispersion solution is watery or oily. Here, particles, such as conductive polymer or superconductor, other than metallic particles containing any one of gold, silver, copper, palladium, and nickel, are used as the conductive particles. In order to improve dispersibility, organic materials are coated on the surface of the conductive particles, and the coated organic materials may be used as the conductive particles. For example, an organic solvent, such as xylene or toluene, or citric acid may be used as a coating material for coating organic materials on the surface of the conductive particles.

It is preferable that the diameter of the conductive particles be greater than or equal to 5 nm and less than or equal to 0.1 μm. If the diameter of the conductive particles is greater than 0.1 μm, clogging may occur in a nozzle of the droplet discharge head. In addition, if the diameter of the conductive particles is less than 5 nm, the volume ratio of the coating material to the conductive particles becomes large, and the ratio of an organic material in an obtained film becomes excessive.

It is preferable that the dispersion medium of liquid containing the conductive particles has a vapor pressure at a room temperature greater than or equal to 0.001 mmHg and less than or equal to 200 mmHg (greater than or equal to about 0.133 Pa and less than or equal to 26600 Pa). If the vapor pressure is greater than 200 mmHg, the dispersion medium is rapidly vaporized after discharge, and it becomes difficult to form a good film. In addition, it is more preferable that the dispersion medium has a vapor pressure greater than or equal to 0.001 mmHg and less than or equal to 50 mmHg (greater than or equal to about 133 Pa and less than or equal to 6650 Pa). If the vapor pressure is greater than 50 mmHg, when droplets are discharged using an ink-jet method, clogging in a nozzle caused by drying may occur easily. Meanwhile, if the dispersion medium has a vapor pressure less than 0.001 mmHg, drying is performed late, and the dispersion medium easily remains in the film, and it is difficult to obtain a good conductive film after the following heat/light treatment.

The dispersion medium is not particularly limited, but any dispersion medium may be used if it can disperse the conductive particles and does not cause cohesion. For example, other than water, alcohols such as methanol, ethanol, propanol, or butanol; hydrocarbon compounds, such as n-heptane, n-octane, decane, toluene, xylene, cymene, durene, indene, dipentene, tetrahydronaphthalene, decahydronaphthalene, and cyclohexylbenzene; ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methylethyl ether, 1,2-dimethoxyethane, bis(2-methoxyethyl)ether, and p-dioxane, and polar compounds such as propylene carbornate, γ-butyrolatone, N-methyl-2-pyrrolidone, dimethylformamide, dimethyl sulfoxide, and cyclohexanone may be used as the dispersion medium. Among the above dispersion mediums, due to the dispersibility of particles, stability of a dispersion solution, and easy application to an ink-jet method, water, alcohols, hydrocarbon compounds, and ether compounds are preferably used, and more preferably, water and hydrogen compounds are used. Single compounds may be used as the dispersion medium, or two or more mixtures may be used as the dispersion medium.

The concentration of a dispersoid when the conductive particles are dispersed in the dispersion medium, is greater than or equal to 1 mass percent or less than or equal to 80 mass percent. The concentration of the dispersoid is adjusted according to the thickness of a predetermined conductive film. In addition, if the concentration of the dispersoid exceeds 80 mass percent, cohesion may easily occur, and it is difficult to obtain a uniform film.

It is preferable that the surface tension of the dispersion solution of the conductive particles be greater than or equal to 0.02 N/m and less than or equal to 0.07 N/m. When droplets are discharged using the ink-jet method, if the surface tension is less than or equal to 0.02 N/m, the wettability of an ink composition on a nozzle surface increases. Therefore, curving flight easily occurs. If the surface tension exceeds 0.07 N/m, the shape of a meniscus at a nozzle tip is not stabilized. Therefore, it is difficult to control the discharge amount of droplets or the discharge timing of droplets.

In order to adjust the surface tension, a small amount of a surface tension regulator, such as a fluorine system, a silicon system, or a nonionic system, is added to the dispersion solution within the range that does not lower a contact angle with a substrate greatly.

The nonionic surface tension regulator is helpful to improve wettability of the liquid to the substrate, to improve leveling property of a film, and to prevent the occurrence of fine unevenness of the film. If necessary, the dispersion solution may include organic compounds, such as alcohols, ether, ester, and ketone.

It is preferable that the viscosity of the dispersion solution be greater than or equal to 1 mPa·s and less than or equal to 50 mPa·s. When a liquid material is discharged as the droplets using the ink-jet method, if the viscosity of the dispersion solution is less than 1 mPa·s, the peripheral portion of a nozzle is easily contaminated by the outflow of ink, and if the viscosity of the dispersion solution is less than 50 mPa·s, the frequency of clogging in a nozzle port is increased, and it is difficult to discharge droplets.

Surface Treatment Step

Next, surface treatment steps S2 and S3 shown in FIG. 1 will be described. In the surface treatment steps, the surface of a substrate for forming conductive film wiring is treated to have a lyophobic property against a liquid material (step S2).

Specifically, surface treatment is performed on the substrate so that a predetermined contact angle with respect to the liquid material containing conductive particles is greater than or equal to 60 [deg], and preferably, greater than or equal to 90 [deg] and less than or equal to 110 [deg]. For example, a method of forming a self-organized film on the surface of a substrate and a plasma treatment method may be used as a method of controlling a lyophobic property (wettability) of the surface.

In the method of forming a self-organized film, the self-organized film formed of an organic molecular film is formed on the surface of a substrate on which conductive film wiring is to be formed. The organic molecular film for treating the surface of the substrate includes a functional group that can be combined with the substrate, a functional group called a lyophilic or lyophobic group and formed at a side opposite to the side in which the functional group is formed, which reforms a surface property (controlling a surface energy) of the substrate, and straight carbon chains used to combine these functional groups or partially-branched carbon chains. Thus, the organic molecular film is combined with the substrate and self organized so that a molecular film such as a monomolecular film is formed.

Here, the self-organized film is formed of a connective functional group that reacts to constituent atoms of a base layer of the substrate, and other linear chain molecule and is formed by aligning compounds having a very high alignment property by an interaction between the linear chain molecules. Since the self-organized film is formed by aligning single molecules, the layer thickness thereof can be made very small, and the self-organized film becomes a uniform film at a molecular level. In other words, since the same molecules are placed on the surface of the film, uniformity and excellent lyophobic property or lyophilic property can be given to the surface of the film.

Fluoroalkylsilane is used as the compounds having the very high alignment property, and each compound is aligned so that a fluoroalkyl group is placed on the surface of the film. As a result, the self-organized film is formed, and a uniform lyophobic property is given to the surface of the film.

Fluoroalkylsilane (hereinafter, referred to as FAS) such as (heptadecafluoro-1,1,2,2-tetrahydrodecyl)triethoxysilane, (heptadecafluoro-1,1,2,2-tetrahydrodecyl)trimethoxysilane, (heptadecafluoro-1,1,2,2-tetrahydrodecyl)trichlorosilane, (tridecafluoro-1,1,2,2-tetrahydrooctyl)triethoxysilane, (tridecafluoro-1,1,2,2-tetrahydrooctyl)trimethoxysilane, (tridecafluoro-1,1,2,2-tetrahydrooctyl)trichlorosilane, and trifluoropropyltrimethoxysilane, may be used as compounds to form the self-organized film. Single compounds may be used, or two or more compounds may be combined with one another. In addition, through the use of FAS, an adhering property with the substrate and a good lyophobic property can be obtained.

In general, FAS is represented by a structural formula RnSiX(4-n). Here, n is an integer greater than or equal to 1 and less than or equal to 3, and X is a hydrolysis group such as a methoxy group, an ethoxy group, and halogen atoms. In addition, R is a fluoroalkyl group and has a structure of (CF3)(CF2)x(CH2)y (where x is an integer greater than or equal to 0 and less than or equal to 10, and y is an integer greater than or equal to 0 and less than or equal to 4). When a plurality of R or X are combined with Si, R or X may be respectively the same as or different from each other. The hydrolysis group represented by X forms silanol by hydrolysis, reacts to a hydroxyl group of the base of a substrate (glass or silicon), and is combined with the substrate by siloxane combination. Meanwhile, since R has a fluoro group, such as CF3, on the surface of the substrate, the base surface of the substrate is reformed on an un-wet surface (having a low surface energy).

The self-organized film formed of an organic molecular film is formed on the substrate by putting the raw material compounds and the substrate in the same airtight container and leaving them alone at a room temperature for two or three days. In addition, the airtight container is maintained at 100° C. for about three hours. The above method is a method of forming the self-organized film from vapor, but the self-organized film may be formed from liquid. For example, the self-organized film is formed on the substrate by dipping the substrate in a solution including raw material compounds and cleaning and drying the substrate. In addition, it is preferable that before forming the self-organized film, pre-treatment of the surface of the substrate be performed by irradiating the surface of the substrate with ultraviolet light or cleaning the substrate using a solvent.

After FAS treatment, if necessary, lyophobic property controlling treatment is performed (step S3) so that the surface of the substrate has a desire lyophobic property. In other words, when FAS treatment is performed as lyophobic treatment, the action of the lyophobic property is so strong that a substrate and a film pattern W formed on the substrate may be easily peeled off. In this case, treatment for lowering (controlling) the lyophobic property is performed. Ultraviolet (UV) irradiation treatment having a wavelength of about 170 to 400 nm may be used as treatment for lowering the lyophobic property. By irradiating the substrate with ultraviolet rays having a predetermined power for a predetermined period of time, the lyophobic property of the substrate on which FAS treatment is performed is lowered, and the substrate has a desired lyophobic property. Alternatively, by exposing the substrate to an ozone atmosphere, the lyophobic property of the substrate can be controlled.

Meanwhile, in the plasma treatment method, the substrate is plasma-irradiated under atmospheric pressure or in a vacuum state. A variety of gases may be selected as gases used in plasma treatment in consideration of the surface material of the substrate on which conductive film wiring is to be formed. For example, 4 fluoromethane, perfluorohexane, or perfluorodecane may be used as treatment gases.

In addition, treatment for processing the surface of the substrate with a lyophobic property may be performed by attaching a film with a desired lyophobic property, for example, a 4 fluoroethylene-processed polyimide film to the surface of the substrate. In addition, a polyimide film having a high lyophobic property may be used as the substrate.

Intermediate Drying step

Next, an intermediate drying step S5 of FIG. 1 will be described. In the intermediate drying step (heat/light treatment step), a dispersion medium or a coating material contained in droplets arranged on a substrate is removed. In other words, the dispersion medium of a liquid material for forming a conductive film arranged on the substrate needs to be completely removed so as to improve electrical contact between particles. In addition, when the surface of conductive particles is coated with a coating material such, as an organic matter, so as to improve the dispersibility thereof, the coating material needs to be removed.

In general, heat/light treatment is performed in air (in an ambient atmosphere), and if necessary, in an inert gas atmosphere, such as nitrogen, argon, or helium. The temperature required for heat/light treatment is properly determined in consideration of the boiling point (vapor pressure) of the dispersion medium, the type or pressure of an atmosphere gas, thermal behavior such as dispersibility or an oxidizability of particles, the existence or amount of a coating material, and a heat-resistant temperature of a material. For example, in order to remove the coating material formed of an organic material, the substrate may be baked at a high temperature of about 300° C. In addition, in the case of using a substrate formed of plastics, it is preferable that the substrate be baked above room temperature and at a temperature less than or equal to 100° C.

A heating apparatus, such as a hot plate or an electric furnace may be used in the heat treatment. Lamp annealing may be used in the light treatment. A light source of light used in lamp annealing is not limited, but an infrared lamp, a xenon lamp, a YAG laser, an argon laser, a carbonic acid gas laser, or an excimer laser such as XeF, XeCl, XeBr, KrF, KrCl, ArF, or ArCl, may be used as the light source. In general, these light sources having an output greater than or equal to 10 W and less than or equal to 5000 W are used, but in the present embodiment, light sources having greater than or equal to 100 W and less than or equal to 1000 W may be well used. Electrical contact between particles is obtained by the heat/light treatment, and a dispersion solution is changed into a conductive film.

In addition, in this case, even though there is no difficulty in increasing the degree of heating or light scanning for removing the dispersion medium and changing the dispersion solution into the conductive film, it is sufficient to remove some of the dispersion medium sufficiently. For example, in the case of heat treatment, in general, heating may be performed at about 100° C. for a few minutes. In addition, drying treatment may be simultaneously performed with discharge of the liquid material. For example, the substrate is heated in advance, or the dispersion medium having a low boiling point is used with cooling of a droplet discharge head so that drying of droplets can be performed immediately after the droplets are arranged on the substrate.

Pattern Forming Apparatus

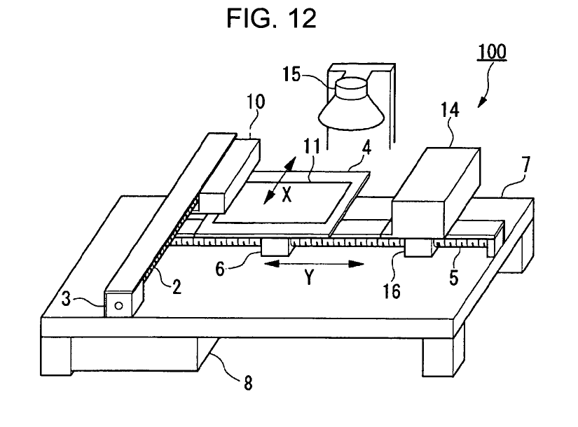

Next, an example of a pattern forming apparatus according to the present invention will be described. FIG. 12 is a schematic perspective view of a pattern forming apparatus according to an embodiment of the present invention. As shown in FIG. 12, a pattern forming apparatus 100 includes a droplet discharge head 10, an X-direction guide shaft 2 for driving the droplet discharge head 10 in an X-direction, an X-direction driving motor 3 for rotating the X-direction guide shaft 2, a mount 4 for mounting a substrate 11 thereon, a Y-direction guide shaft 5 for driving the mount 4 in a Y-direction, a Y-direction driving motor 6 for rotating the Y-direction guide shaft 5, a cleaning mechanism 14, a heater 15, and a controller 8 for controlling the elements. The X-direction guide shaft 2 and the Y-direction guide shaft 5 are fixed on a base 7. In addition, in FIG. 12, even though the droplet discharge head 10 is arranged to be perpendicular to an advancing direction of the substrate 11, the angle of the droplet discharge head 10 may be adjusted so that the droplet discharge head 10 may intersect the advancing direction of the substrate 11. In this way, the pitch between nozzles can be adjusted by adjusting the angle of the droplet discharging head 10. In addition, the distance between a nozzle surface and the substrate 11 can be arbitrarily adjusted.

The droplet discharge head 10 discharges a liquid material formed of a dispersion solution containing conductive particles through a nozzle discharge and is fixed on the X-direction guide shaft 2. The X-direction driving motor 3 is a stepping motor, and if a driving pulse signal in an X-axis direction is supplied from the controller 8 to the X-direction driving motor, the X-direction driving motor 3 rotates the X-direction guide shaft 2. By rotation of the X-direction guide shaft 2, the droplet discharge head 10 moves in the X-axis direction with respect to the base 7.

Droplet discharge methods may include a variety of well-known techniques such as a piezo-method of discharging ink using a piezo-element that is a piezoelectric element, and a bubble method of discharging a liquid material through bubbles generated from the heated liquid material. In the piezo-method, since heat is not applied to the liquid material, the composition of the material is not affected. In addition, because of a high degree of freedom in selection of the liquid material and good control of the droplets, the piezo-method is preferred in the present embodiment.

The mount 4 is fixed on the Y-direction guide shaft 5, and Y-direction driving motors 6 and 16 are connected to the Y-direction guide shaft 5. The Y-direction driving motors 6 and 16 are stepping motors, and if a driving pulse signal in a Y-axis direction is supplied from the controller 8 to the Y-direction driving motors 6 and 16, the Y-direction driving motors 6 and 16 rotate the Y-direction guide shaft 5. By rotation of the Y-direction guide shaft 5, the mount 4 moves in the Y-axis direction with respect to the base 7. The cleaning mechanism 14 cleans the droplet discharge head 10 and prevents clogging of a nozzle. The cleaning mechanism 14 moves along the Y-direction guide shaft 5 by the Y-direction driving motor 16 during cleaning. The heater 15 heats the substrate 11 using heating means, such as lamp annealing, performs vaporization/drying of discharged liquid on the substrate 11, and performs heat treatment for changing a dispersion solution into a conductive film.

In the pattern forming apparatus 100 according to this embodiment, by relatively moving the substrate 11 and the droplet discharge head 10 by the X direction driving motor 3 and the Y direction driving motor 6 while discharging the liquid material from the droplet discharge head 10, the liquid material is arranged on the substrate 11. The amount of droplets discharged from each nozzle of the droplet discharge head 10 is controlled by a voltage supplied to the piezoelectric element from the control unit 8. Further, the pitch of the droplets arranged on the substrate 11 is controlled by the relative movement speed and an arrangement frequency from the droplet discharge head 10 (a frequency of the driving voltage to the piezoelectric element). Furthermore, the position at which the arrangement of the droplets on the substrate 11 is started is controlled by a direction of the relative movement and a timing control of the arrangement start of the droplets from the droplet discharge head 10, etc. during the relative movement. As a result, the conductive film patterns for the wiring described above are formed on the substrate 11.

Electro-Optical Device

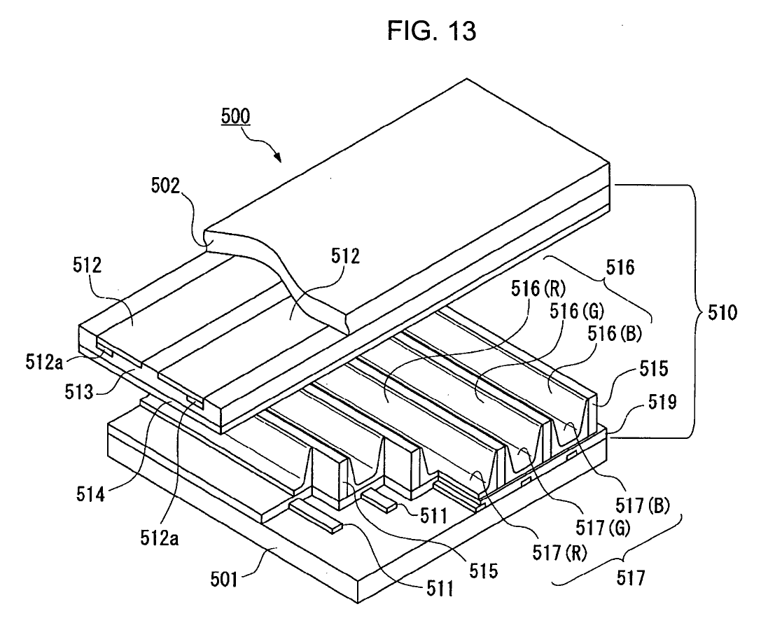

Next, a plasma display device as an example of an electro-optical device according to the present invention will be described. FIG. 13 is an exploded perspective view of a plasma display device 500 according to the present embodiment. The plasma display device 500 includes substrates 501 and 502 arranged to be opposite to each other, and a discharge display unit 510 formed therebetween. The discharge display unit 510 is formed of a plurality of discharge chambers 516. Three discharge chambers 516, such as a red discharge chamber 516(R), a green discharge chamber 516(G), and a blue discharge chamber 516(B), of the plurality of discharge chambers 516 are paired to form one pixel.

Address electrode 511 are formed on the top face of the substrate 501 in a stripe shape at predetermined intervals, and a dielectric layer 519 is formed to cover the address electrodes 511 and the top face of the substrate 501.

Partition walls 515 are formed on the dielectric layer 519 to be positioned between address electrodes 511, 511 and run along each address electrode 511. The partition walls 515 include a partition portion adjacent to widthwise right and left sides of the address electrode 511 and a partition portion that extends in a direction perpendicular to the address electrode 511. In addition, a discharge chamber 516 is formed to correspond to a rectangular region partitioned by the partition wall 515. In addition, a fluorescent material 517 is arranged inside the rectangular region partitioned by the partition wall 515. The fluorescent material 517 emits fluorescence having one of red, green, blue colors, and a red fluorescent material 517(R) is arranged at the bottom of the red discharge chamber 516(R), a green fluorescent material 517(G) is arranged at the bottom of the green discharge chamber 516(G), and a blue fluorescent material 517(B) is arranged at the bottom of the blue discharge chamber 516(B).

Meanwhile, a plurality of display electrodes 512 are formed on the substrate 502 in a stripe shape at predetermined intervals in a direction perpendicular to the previous address electrodes 511. Further, a dielectric layer 513 and a protection layer 514 formed of MgO are formed to cover the plurality of display electrodes 512. The substrate 501 and the substrate 502 are opposite to each other and are attached to each other so that the display electrodes 512 . . . are perpendicular to the address electrodes 511 . . . . The address electrodes 511 and the display electrodes 512 are connected to an AC power source (not shown). A current flows through each electrode so that the fluorescent material 517 is excited to emit light in the discharge display unit 510, thereby allowing color display.

In the present embodiment, the address electrodes 511 and the display electrodes 512 are respectively formed by the pattern forming method of FIGS. 1 to 11 using the pattern forming apparatus of FIG. 12. For this reason, the line widths of the wiring lines can be made to be uniform, and it is also possible to provide a display device having an excellent visibility without a lack of uniformity in appearance between the wiring lines.

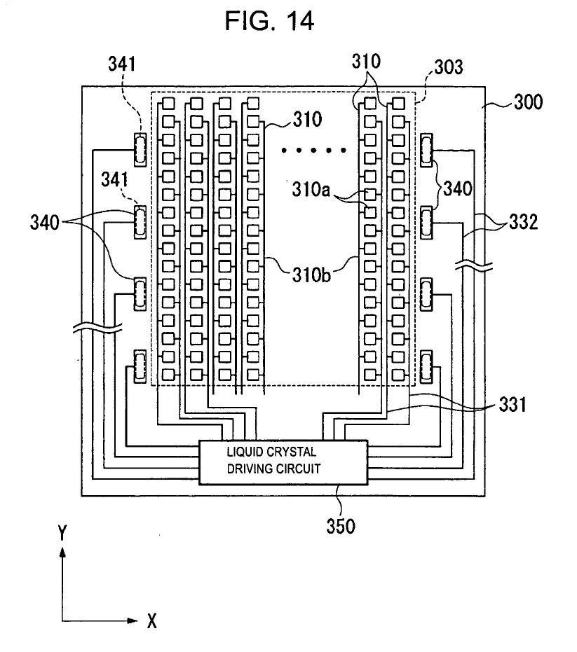

Next, a liquid crystal device as another example of the electro-optical device according to the present invention will be described. FIG. 14 shows a plan layout of a signal electrode on a first substrate of the liquid crystal device according to the present embodiment. The liquid crystal device according to the present embodiment generally includes the first substrate, a second substrate (not shown) on which scanning electrodes are formed, and liquid crystal (not shown) enclosed between the first substrate and the second substrate.

As shown in FIG. 14, a plurality of signal electrodes 310 . . . is provided in a multi-matrix in a pixel region 303 on the first substrate 300. In particular, the respective signal electrodes 310 . . . include a plurality of pixel electrode portions 310a. . . corresponding to respective pixel and signal wiring portions 310b. . . for connecting the pixel electrode portions 310a. . . in the multi-matrix and extend in a Y-direction. In addition, reference numeral 350 denotes a liquid crystal driving circuit having one-chip structure. The liquid crystal driving circuit 350 is connected to one end (lower side in the drawing) of each of the signal wiring portion 310b. . . via first pull-in wiring 331 . . . . In addition, reference numeral 340 . . . denotes up-down conducting terminals. The up-down conducting terminals 340 . . . and terminals (not shown) formed on the second substrate are connected to each other by up-down conducting materials 341. In addition, the liquid crystal driving circuit 350 and the up-down conducting terminals 340 . . . are connected to each other via second pull-in wiring 332 . . . .

In the present embodiment, the respective signal wiring portions 310b. . . , the first pull-in wiring 331 . . . , and the second pull-in wiring 332 . . . , which are formed on the first substrate 300, are formed by the pattern forming method described referring to FIGS. 1 to 11 using the pattern forming apparatus as shown in FIG. 12. For this reason, it is possible to form wirings having uniform line width. In addition, even when manufacturing a large-sized liquid crystal substrate, a wiring material can be effectively used, and costs can be reduced. In addition, a device to which the present invention can be applied is not limited to the electro-optical device, and the present invention can be applied to manufacturing other devices, such as a circuit board on which conductive film wiring is formed, or mounting wiring of a semiconductor.

Next, a liquid crystal display device as an electro-optical device according to another embodiment of the present invention will be described.

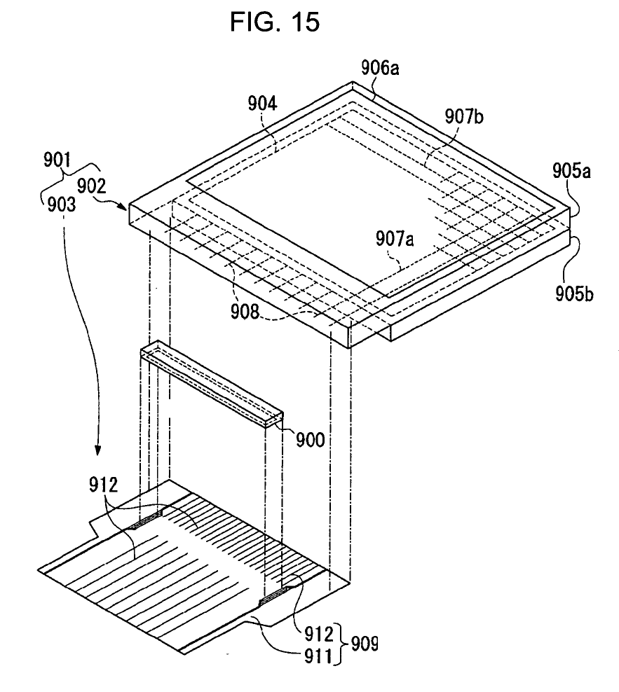

A liquid crystal device (electro-optical device) 901 of FIG. 15 largely includes a color liquid crystal panel (electro-optical panel) 902 and a circuit board 903 connected to the liquid crystal panel 902. In addition, if necessary, an illuminator, such as a backlight and other auxiliary devices, are provided in the liquid crystal panel 902.

The liquid crystal panel 902 includes a pair of substrates 905a and 905b bonded to each other using a sealing material 904, and liquid crystal is filled in a gap called a cell gap between the substrates 905a and 905b. In general, the substrates 905a and 905b are formed of a light-transmitting material, for example, glass or synthetic resin. Polarizing plates 906a and 906b are attached to the outer surfaces of the substrates 905a and 905b, respectively. In addition, the polarizing plate 906b is omitted in FIG. 15.

In addition, electrodes 907a are formed on the inner surface of the substrate 905a, and electrodes 907b are formed on the inner surface of the substrate 905b. The electrodes 907a and 907b are formed in a stripe, character, number, or other proper pattern. In addition, the electrodes 907a and 907b are formed of a light-transmitting material such as indium tin oxide (ITO). The substrate 905a includes a protruding portion with respect to the substrate 905b, and a plurality of terminals 908 are formed in the protruding portion. The terminals 908 are formed simultaneously with the electrode 907a when the electrode 907a is formed on the substrate 905a. Thus, the terminals 908 are formed of ITO, for example. The terminals 908 include terminals extending integrally from the electrodes 907a and terminals connected to the electrodes 907b via a conductive material (not shown).

A semiconductor element 900 which is a liquid crystal driving IC, is mounted in a predetermined position on a wiring board 909 of the circuit board 903. In addition, although not shown, a resistor, a storage capacitor, and other chip components may be mounted in the predetermined position of a portion other than a portion on which the semiconductor element 900 is mounted. The wiring board 909 is manufactured by patterning a metallic layer such as Cu formed on a base substrate 911 having flexibility, such as polyimide, and by forming a wiring pattern 912.

In the present embodiment, the electrodes 907a and 907b of the liquid crystal panel 902 and the wiring pattern 912 of the circuit board 903 are formed by the method of forming a device.

According to the liquid crystal device of the present embodiment, a high-quality liquid crystal display device in which non-uniformity of electric characteristics is removed can be obtained.

In addition, the above-described example is a passive liquid crystal panel, but may be an active-matrix liquid crystal panel. In other words, a thin film transistor (TFT) is formed on one substrate, and a pixel electrode is formed on each TFT. In addition, wiring (gate wiring and source wiring) electrically connected to each TFT can be formed using an ink-jet technique as described above. Meanwhile, a counter electrode is formed on a counter substrate. The present invention can be applied to the active-matrix liquid crystal panel.

Next, a field emission display (FED) having a field emission element (electron emission element) of an electro-optical device according to another embodiment of the present invention will be described.

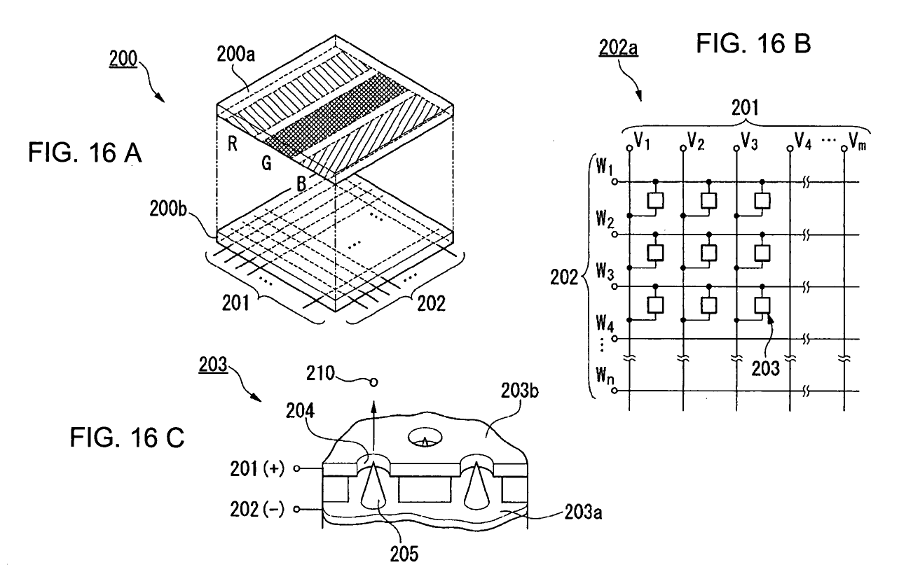

FIGS. 16A-C are views illustrating the FED. FIG. 16(a) schematically shows the arrangement of a cathode substrate and an anode substrate that constitute the FED. FIG. 16(b) is a mimetic diagram of a driving circuit of the cathode substrate of the FED. FIG. 16(c) is a perspective view of a main part of the cathode substrate.

As shown in FIG. 16(a), an FED (electro-optical device) 200 has a structure in which the cathode substrate 200a and the anode substrate 200b are arranged opposite to each other. As shown in FIG. 16(b), the cathode substrate 200a includes a gate line 201, an emitter line 202, and a field emission element 203 connected to the gate line 201 and the emitter line 202. In other words, the cathode substrate 200a becomes a so-called simple matrix driving circuit. Gate signals V1, V2, . . . , and Vm are supplied to the gate line 201, and emitter signals W1, W2, . . . , and Wn are supplied to the emitter line 202. In addition, the anode substrate 200b includes a fluorescent material formed of R, G, and B and has a property in which electrons hit a corresponding fluorescent material to emit light.

As shown in FIG. 16(c), the field emission element 203 includes an emitter electrode 203a connected to the emitter line 202 and a gate electrode 203b connected to the gate line 201. Further, the emitter electrode 203a has a protrusion called an emitter tip 205 whose diameter becomes smaller from the emitter electrode 203a to the gate electrode 203b, and a hole 204 is formed in the gate electrode 203b in a position corresponding to the emitter tip 205, and a tip of the emitter tip 205 is arranged in the hole 204.

With regard to the FED 200, gate signals V1, V2, . . . , and Vm of the gate line 201 and emitter signals W1, W2, . . . , and Wn of the emitter line 202 are controlled so that a voltage is supplied between the emitter electrode 203a and the gate electrode 203b, an electron 210 moves toward the hole 204 from the emitter tip 205 by electrolytic action, and the electron 210 is emitted from the tip of the emitter tip 205. Here, since the corresponding electron 210 hits the fluorescent material of the anode substrate 200b to emit light, a desired FED 200 can be driven.

With regard to the FED having the above structure, for example, the emitter electrode 203a or the emitter line 202, or the gate electrode 203b or the gate line 201 is formed by the method of forming a device.

According to the FED of the present embodiment, a high-quality FED in which non-uniformity of electric characteristics is removed can be obtained.

Electronic Apparatus

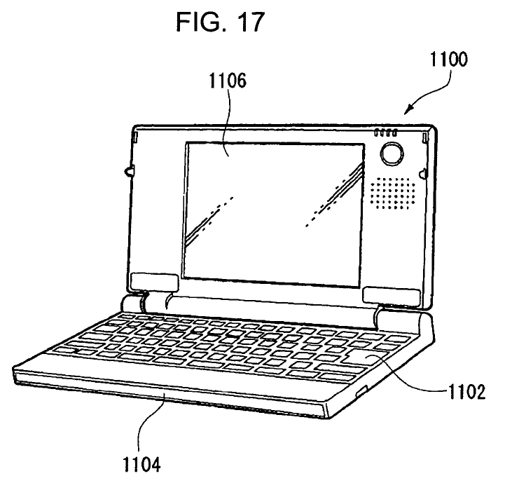

Next, an example of the electronic apparatus according to the present invention will be described. FIG. 17 is a perspective view showing the structure of a mobile personal computer (information processor) having a display device according to the above-described embodiment. In FIG. 17, the personal computer 1100 includes a main body 1104 having a keyboard 1102 and a display device unit having the above-described electro-optical device 1106. Thus, the electronic apparatus having a high luminous efficiency and a bright display unit can be provided.

In addition to the above-described example, as other examples, the electronic apparatus includes a mobile telephone, a wrist watch electronic apparatus, a liquid crystal TV, a video tape recorder of view finder type or monitor direct-viewing type, a car navigation apparatus, a pager, an electronic note, an electronic calculator, a word processor, a workstation, a mobile phone, a POS terminal, an electronic paper, and an apparatus having a touch panel. The electro-optical device according to the present invention can also be applied to a display unit of the electronic apparatus. In addition, the electronic apparatus according to the present embodiment includes an electronic apparatus having other electro-optical devices having a liquid crystal device, an organic electroluminescent display device, and a plasma display device.

As described above, although preferred embodiments of the present invention has been particularly shown and described with reference to the accompanying drawings, it goes without saying that the present invention is not limited to the above embodiments. Various shapes or combinations of the respective elements as shown in the above-described embodiments are just examples, and various changes may be made depending on design requirements without departing from the spirit of the present invention.

1. A pattern forming method of forming film patterns by arranging droplets of a liquid material on a substrate, the method comprising the steps of:
defining a plurality of pattern forming areas on the substrate in which the film patterns are intended to be formed; and
sequentially arranging a plurality of droplets in the plurality of defined pattern forming areas to form the film patterns,
wherein the droplets are sequentially arranged by setting an arrangement order of the droplets to be substantially equal in the plurality of pattern forming areas.

2. The pattern forming method according to claim 1,
wherein a plurality of unit areas having a lattice shape in which the droplets are arranged are defined on the substrate, and the droplets are arranged in a predetermined unit area of the plurality of unit areas.

3. The pattern forming method according to claim 1,
wherein the droplets are arranged essentially simultaneously in the plurality of pattern forming areas.

4. The pattern forming method according to claim 1,
wherein the film patterns are line-shaped patterns, side portions in a line-width direction of the film patterns are first formed, and then central portions of the film patterns are formed.

5. The pattern forming method according to claim 1,
wherein the plurality of pattern forming areas are arranged and defined in a predetermined direction, a plurality of discharge portions for arranging the droplets are provided to correspond to the plurality of pattern forming areas, respectively, and the droplets are arranged while moving the discharge portions in the arrangement direction of the pattern forming areas.

6. The pattern forming method according to claim 1,
wherein the liquid material comprises conductive particles.

7. A pattern forming method of forming line-shaped film patterns by arranging droplets of a liquid material on a substrate, the method comprising the steps of:
defining a plurality of pattern forming areas on the substarte in which the film patterns are intended to be formed; and
arranging the plurality of droplets in the plurality of defined pattern forming areas, the droplets overlapping a part of the pattern forming areas, to form the film patterns,
wherein the arrangement of the droplets is set to be substantially equal in the plurality of pattern forming areas.

8. A pattern forming apparatus comprising:
a droplet discharge device for arranging droplets of a liquid material on a substrate and forming film patterns out of the droplets,
wherein the droplet discharge device sequentially arranges the plurality of droplets in a plurality of pattern forming areas which are pre-defined on the substrate and in which the film patterns are intended to be formed, and when the droplets are sequentially arranged, an arrangement order of the droplets is set to be substantialy equal in the plurality of pattern forming areas.

9. A pattern forming apparatus comprising:
a droplet discharge device for arranging droplets of a liquid material on a substrate and forming line-shaped film patterns out of the droplets,
wherein the droplet discharge device arranges the plurality of droplets in a plurality of pattern forming areas which are pre-defined on the substrate and in which the film patterns are intended to be formed, the droplets overlapping a part of the pattern forming areas, and when the droplets are sequentially arranged, the arrangement of the droplets is set to be substantially equal in the plurality of pattern forming areas.

10. A method of manufacturing a device having wiring patterns, the method comprising:
a material arranging step of forming the wiring patterns by arranging droplets of a liquid material in a plurality of pattern forming areas which are defined on a substrate and in which the wiring patterns are intended to be formed,
wherein the material arranging step includes a step of forming the wiring patterns by sequentially arranging the plurality of droplets in the plurality of defined pattern forming areas, and
wherein the droplets are sequentially arranged by setting an arrangement order of the droplets to be substantially equal in the plurality of pattern forming areas.

11. A method of manufacturing a device having wiring patterns, the method comprising:
a material arranging step of forming the wiring patterns by arranging droplets of a liquid material in a plurality of pattern forming areas which are defined on a substrate and in which the wiring patterns should be formed,
wherein the material arranging step includes a step of forming the wiring patterns by arranging the plurality of droplets in the plurality of defined pattern forming areas, the droplets overlapping a part of the pattern forming areas, and
wherein the arrangement of the droplets is set to be substantially equal in the plurality of pattern forming areas.

12. Conductive film wiring formed using the pattern forming apparatus according to claim 8.

13. Conductive film wiring formed using the pattern forming apparatus according to claim 9.

14. Conductive film wiring comprising a plurality of wiring patterns arranged on a substrate,
wherein the plurality of wiring patterns are formed out of a plurality of droplets arranged to overlap a part of the wiring patterns, and the arrangement of the plurality of droplets is set to be substantially equal in the plurality of wiring patterns.

15. An electro-optical device comprising conductive film wiring according to claim 12.

16. An electronic apparatus comprising an electro-optical device according to claim 15.

17. An electro-optical device comprising conductive film wiring according to claim 13.

18. An electronic apparatus comprising an electro-optical device according to claim 17.

19. An electro-optical device comprising conductive film wiring according to claim 14.

20. An electronic apparatus comprising an electro-optical device according to claim 19.
